(19) United States
(12) Patent Application Publication
(10) Pub. No.: US 2009/0146237 A1
(43) Pub. Date: Jun. 11, 2009

(54) IMAGE SENSOR AND METHOD FOR MANUFACTURING THEREOF

(76) Inventor: Young-Je Yun, Ansan-si (KR)

Correspondence Address: SHERR & VAUGHN, PLLC, 620 HERNDON PARKWAY, SUITE 200, HERNDON, VA, 20170, US

(21) Appl. No.: 12/330,647

(22) Filed: Dec. 9, 2008

(30) Foreign Application Priority Data
Dec. 11, 2007 (KR) 10-2007-0128281

(51) Int. Cl. H01L 31/101; H01L 21/02

(52) U.S. Cl. 257/432; 438/69; 257/E31.127; 257/E21.002

(57) ABSTRACT

An image sensor and a method for manufacturing thereof include a semiconductor substrate having a plurality of unit pixels formed therein, a dielectric film formed over the semiconductor substrate, a seed lens array including a plurality of seed lenses formed spaced apart by a gap of a predetermined width over the dielectric film, a color micro lens array formed over the seed lens array, the color micro lens array including a color micro lens formed over and contacting a respective one of the seed lenses. In accordance with embodiments, each color micro lens has a thickness that is one-half the predetermined width to thereby fill the gap between the seed lenses.

The present application claims priority under 35 U.S.C. §119 to Korean Patent Application No. 10-2007-0128281 (filed on Dec. 11, 2007), which is hereby incorporated by reference in its entirety.

### BACKGROUND

An image sensor is a semiconductor device converting an optical image into an electrical signal. An image sensor may be classified into a charge coupled device (CCD) image sensor and a complementary metal oxide silicon (CMOS) image sensor (CIS). The CMOS image sensor forms a photodiode and a MOS transistor within a unit pixel to sequentially detect electrical signals of each unit pixel, implementing an image. As a design rule in the CMOS image sensor has been gradually reduced, size of the unit pixel is also reduced so that photosensitivity may be reduced. In order to improve such photosensitivity, a micro lens is formed on a color filter. However, since a receiving light area becomes narrow in accordance with an integration of a device, there is a demand for improving a fill factor of a photodiode.

### SUMMARY

Embodiments relate to an image sensor and a method for manufacturing thereof that maximizes a fill factor by reducing a focal length between a photodiode and a micro lens.

In accordance with embodiments, an image sensor may include at least one of the following: a semiconductor substrate including at least one unit pixel; an interlayer dielectric film including a metal wire formed on and/or over the semiconductor substrate; at least one seed lens formed on and/or over the interlayer dielectric film and formed having a semi-circular cross-section with a reciprocal gap area; and at least one color micro lens formed on and/or over the surface of the at least one seed lens.

In accordance with embodiments, a device may include at least one of the following: a semiconductor substrate having a unit pixel formed therein; a dielectric film including a metal wire formed over the semiconductor substrate; a seed lens formed over the dielectric film; and a micro lens formed over the seed lens such that the microlens is composed of a dyed photoresist material.

In accordance with embodiments, a device may include at least one of the following: a semiconductor substrate having a plurality of unit pixels formed therein; a dielectric film formed over the semiconductor substrate; a seed lens array including a plurality of seed lenses formed spaced apart by a gap of a predetermined width over the dielectric film; a color micro lens array formed over the seed lens array, the color micro lens array including a plurality of micro lenses formed over and contacting a respective one of the seed lenses, whereby each micro lens has a thickness that is one-half the predetermined width to fill the gap; and a protective cap layer formed over and contacting the micro lens array.

In accordance with embodiments, a method may include at least one of the following: providing a semiconductor substrate having a plurality of unit pixels formed therein; and then forming a dielectric film over the semiconductor substrate; and then forming a seed lens array including a plurality of seed lenses formed spaced apart by a gap of a predetermined width over the dielectric film; and then forming a color micro lens array over the seed lens array, the color micro lens array including a color micro lens formed over and contacting a respective one of the seed lenses, whereby each color micro lens has a thickness that is one-half the predetermined width.

In accordance with embodiments, a method for manufacturing an image sensor may include at least one of the following: forming an interlayer dielectric film including a metal wire on and/or over a semiconductor substrate including at least one unit pixel; forming a plurality of seed lenses spaced apart on and/or over the interlayer dielectric film by a gap area; and forming a color micro lens on and/or over the surface of each seed lenses.

### DRAWINGS

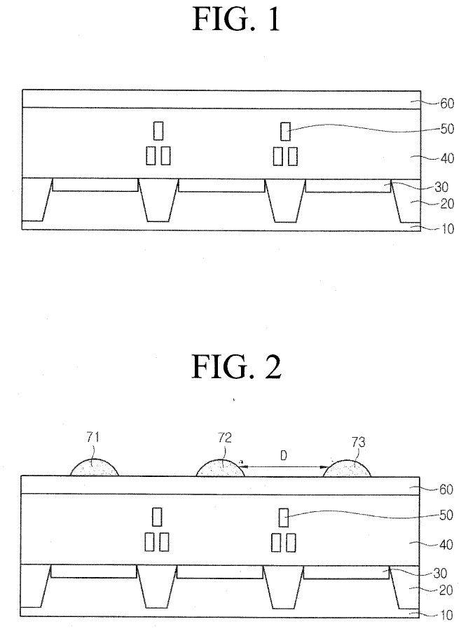

Example FIGS. 1 to 5 illustrate a method for manufacturing an image sensor in accordance with embodiments.

### DESCRIPTION

Example FIGS. 1 to 5 are cross-sectional views of a method for manufacturing an image sensor in accordance with embodiments. Referring to example FIG. 1, interlayer dielectric layer 40 including metal wire 50 is formed on and/or over semiconductor substrate 10 including unit pixel 30. Device isolation film 20 defining an active area and a field area is formed in semiconductor substrate 10. Unit pixel 30 is formed in the active area and includes a photodiode which generates photocharges by receiving light and a CMOS circuit which converts the photocharges of light received by being connected to the photodiode into electrical signals.

After other devices including unit pixel 30 are formed, metal wire 50 and interlayer dielectric film 40 are formed on and/or over semiconductor substrate 10. Interlayer dielectric film 40 may be formed in multiple layers. For example, interlayer dielectric film 40 may include a nitride film or an oxide film. A plurality of metal wires 50 may be formed penetrating through interlayer dielectric film 40. Metal wire 50 is formed so as to not block light incident on and/or over the photodiode. Metal wire 50 may include various conductive materials including metal, alloy or silicide. For example, metal wire 50 may include at least one of aluminum, copper, cobalt and tungsten. Passivation layer 60 may be formed on and/or over interlayer dielectric film 40. Passivation layer 60, which protects devices from moisture and scratching, may include a dielectric film. For example, passivation layer 60 may include at least one of a silicon oxide film, a silicon nitride film and a silicon oxynitride film, or has a stacked multi-layered structure. Alternatively, a subsequent process may be performed on interlayer dielectric film 40, omitting the formation of passivation layer 60. This affects the overall height of the image sensor, making it possible form a thinner image sensor and/or reduce overall manufacturing costs due to a reduction in processes.

Referring to example FIG. 2, a seed lens array is formed on and/or over passivation layer 60 (or interlayer dielectric film 40). Seed lens array includes first seed lens 71, second seed lens 72 and third seed lens 73 formed spaced apart by a gap. Each one of first seed lens 71, second seed lens 72 and third seed lens 73 may correspond to a respective unit pixel 30. In order to form the seed lens array, a photoresist film is formed by coating photoresist for forming a micro lens on and/or over passivation layer 60 through a spin process. The photoresist film is patterned by exposure and development processes to correspond to unit pixel 30, thereby forming a seed pattern. The seed pattern may be patterned spaced apart from a neighboring seed pattern. Thereafter, a reflow process is performed on the seed pattern to form a seed lens array including a seed lens having a semispherical cross-section and a convex surface. The seed lens array including first seed lens 71, second seed lens 72 and third seed lens 73 are spaced apart a predetermined distance denoted by gap D. The predetermined distance of gap D may be in a range between approximately 1.0 to 1.5 μm. First seed lens 71, second seed lens 72 and third seed lens 73 may have a refractive index in a range between approximately 1.5 to 1.7. Therefore, first seed lens 71, second seed lens 72 and third seed lens 73 are formed to each correspond to a respective unit pixel 30 in semiconductor substrate 10, thereby making it possible to allow incident light to be condensed into unit pixel 30.

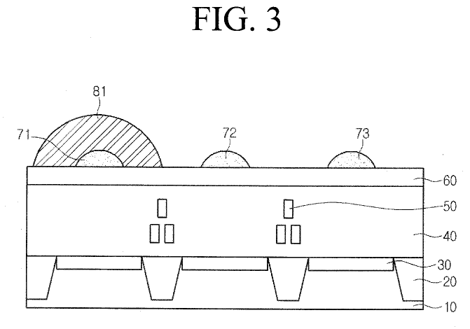

Referring to example FIG. 3, first color micro lens 81 is formed on and/or over first seed lens 71. First color micro lens 81 may be formed only on and/or over first seed lens 71 using a dyed photoresist. First color micro lens 81 may be formed by a negative photoresist. First color micro lens 81 may be formed by a dyed photoresist representing red. The dyed photoresist has a physical property to be formed on and/or over the surface of the underlying first seed lens 71. First color micro lens 81 may be formed to fill one-half of gap D. For example, first color micro lens 81 may be formed at a thickness in a range between approximately 5000 to 8000 Å. First color micro lens 81 may be formed having semispherical cross-section and a convex surface such as first seed lens 71. First color micro lens 81 may be made of color filter material having a refractive index in a range between approximately 1.5 to 1.7. Therefore, light passing through first color micro lens 81 and first seed lens 71 may be refracted to be light condensed into unit pixel 30.

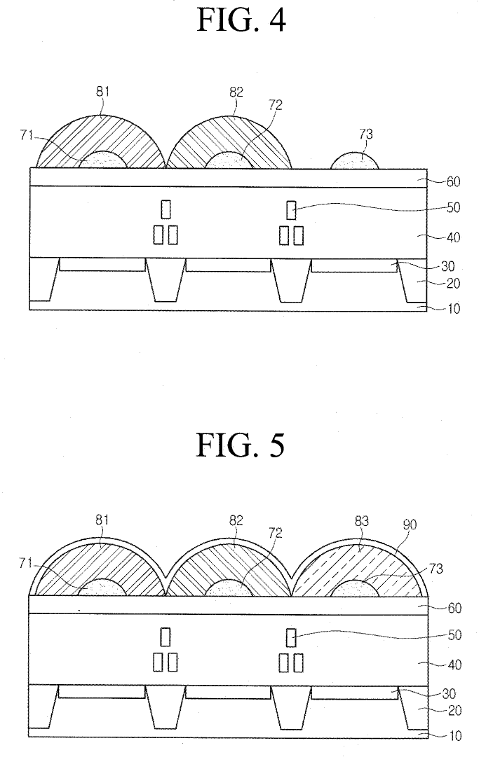

Referring to example FIG. 4, second color micro lens 82 is formed on and/or over second seed lens 72. Second color micro lens 82 may be formed only on and/or over second seed lens 72 using a dyed photoresist. Second color micro lens 82 may be formed of a negative photoresist a first color micro lens 81. Second color micro lens 82 may be formed by a dyed photoresist representing green. Second color micro lens 82 may be formed to fill one-half of gap D. For example, the first color micro lens 82 may be formed at a thickness in a range between approximately 5000 to 8000 Å. Second color micro lens 82 may be formed having semispherical cross-section and a convex surface on and/or over second seed lens 72. Gap D between first seed lens 71 and second seed lens 72 may be removed by formation of first microlens 81 and second color micro lens 82. Therefore, first color micro lens 81 and second color micro lens 82 may implement a zero-gap.

Referring to example FIG. 5, third color micro lens 83 is formed on and/or over third seed lens 73. Third color micro lens 83 may be formed in the same method and material as first micro lens 81 and second color micro lens 82. However, third color micro lens 83 may be formed by a dyed photoresist representing blue. Therefore, third color micro lens 83 may be formed having semispherical cross-section and a convex surface on and/or over third seed lens 73. Third color micro lens 83 may be formed filling one-half of gap D, making it possible to implement a zero-gap with the neighboring second color micro lens 82.

Protective cap layer 90 may be formed on and/or over first seed lens 71, second seed lens 72 and third seed lens 73. Protective cap layer 90 may be composed of thermosetting resins at a thickness in a range between approximately 50 to 500 Å. Protective cap 90 may be composed of a transparent material and has extinction coefficient K for visible rays of 0, making it possible to protect first micro lens 81, second micro lens 82 and third micro lens 83 while also not adversely effecting the refractive index of first micro lens 81, second micro lens 82 and third micro lens 83. Protective cap 90 also serves to protect first micro lens 81, second micro lens 82 and third micro lens 83 from being damaged by chemical attack and moisture applied during various processes such as cleaning and also final packaging.

Accordingly, as illustrated in example FIG. 5, an image sensor in accordance with embodiments may include interlayer dielectric film 40 including metal wire 50 formed on and/or over semiconductor substrate 10 including unit pixel 30. Unit pixel 30 of semiconductor substrate 10 includes a photodiode for receiving light and a transistor for processing photocharges of light received in the photodiode. Metal wire 50 and interlayer dielectric film 40 may be formed in multi layers. Metal wires 50 are electrically connected to each other in order to be connected to a power line and a signal line. Passivation layer 60 for protecting an element including unit pixel 30 and metal wire 50 is formed on and/or over interlayer dielectric layer 40.

A seed lens array that includes first seed lens 71, second seed lens 72 and third seed lens 73 is formed on and/or over passivation layer 60 to correspond to unit pixel 30. First seed lens 71, second seed lens 72 and third seed lens 73 may be formed having a semispherical cross-section and composed of a photoresist. First seed lens 71, second seed lens 72 and third seed lens 73 are spaced apart a predetermined distance or gap D. Gap D may be in a range between approximately 1.0 to 1.5 μm. First color micro lens 81, second color micro lens 82 and third color micro lens 83 are disposed on and/or over a corresponding unit pixel 30 and also first seed lens 71, second seed lens 72 and third seed lens 73, respectively. First color micro lens 81, second color micro lens 82 and third color micro lens 83 may be formed having a semispherical cross-section like the underlying seed lenses 71, 72 and 73. For example, first color micro lens 81 may be red, second color micro lens 82 may be green, and third color micro lens 83 may be blue. In other words, the respective color micro lenses 81, 82 and 83 may be made of materials for color filters.

First color micro lens 81, second color micro lens 82 and third color micro lens 83 may have a zero-gap with a neighboring micro lens. For example, first color micro lens 81, second color micro lens 82 and third color micro lens 83 may be formed at a thickness in a range between approximately 5000 to 8000 Å so that gap D of first seed lens 71, second seed lens 72 and third seed lens 73 may be removed. In other words, the respective thickness of first color micro lens 81, second color micro lens 82 and third color micro lens 83 may be half of gap D. The refractive index of first color micro lens 81, second color micro lens 82 and third color micro lens 83 and first seed lens 71, second seed lens 72 and third seed lens 73 is in a range between approximately 1.5 to 1.7 so that visible rays can be condensed into unit pixel 30 in substrate 10 through first color micro lens 81, second color micro lens 82 and third color micro lens 83.

Protective cap 90 is formed on and/or over first color micro lens 81, second color micro lens 82 and third color micro lens 83. For example, protective cap 90 may be made of thermosetting resins at a thickness in a range between approximately 50 to 500 Å. Protective cap 90 may be composed of a transparent material having a refractive index of substantially 0 I order not to adversely effect the refractive index of first color micro lens 81, second color micro lens 82 and third color micro lens 83. Protective cap 90 can also protect the surfaces of first color micro lens 81, second color micro lens 82 and third color micro lens 83 from external damage and debris.

In accordance with embodiments, a micro lens array having no gap between neighboring microlenses can be formed on and/or over first seed lens 71, second seed lens 72 and third seed lens 73. Therefore, generation of crosstalk and noise can be prevented. In accordance with embodiments, since processes for forming a color filter array and a planarization layer are omitted, the overall thickness of the image sensor is reduced, making it possible to reduce the focal length between a micro lens and a corresponding photodiode. Therefore, embodiments can maximize the fill factor of the photodiode. Since the color micro lenses are formed on and/or over the seed lens array, productivity can be maximized by reducing the overall number of processes, particularly, forming a planarization layer, a color filter and a micro lens, and mask processes.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A device comprising:
a semiconductor substrate having a unit pixel formed therein;
a dielectric film including a metal wire formed over the semiconductor substrate;
a seed lens formed over the dielectric film; and
a micro lens formed over the seed lens, wherein the microlens is composed of a dyed photoresist material.

2. The device of claim 1, wherein the device comprises an image sensor.

3. The device of claim 1, further comprising a protective cap layer formed over the micro lens.

4. The device of claim 1, further comprising a passivation layer formed interposed between the dielectric film and the seed lens.

5. A device comprising:
a semiconductor substrate having a plurality of unit pixels formed therein;
a dielectric film formed over the semiconductor substrate;
a seed lens array including a plurality of seed lenses formed spaced apart by a gap of a predetermined width over the dielectric film;
a color micro lens array formed over the seed lens array, the color micro lens array including a color micro lens formed over and contacting a respective one of the seed lenses, wherein each color micro lens has a thickness that is one-half the predetermined width; and
a protective layer formed over and contacting the color micro lens array.

6. The device of claim 5, wherein the dielectric layer comprises one of an oxide layer and a nitride layer.

7. The device of claim 5, further comprising a passivation layer formed interposed between the dielectric film and the seed lens array.

8. The device of claim 7, wherein the passivation layer comprises one of a silicon oxide film, a silicon nitride film and a silicon oxynitride film.

9. The device of claim 5, wherein the predetermined width is in a range between approximately 1.0 to 1.5 μm.

10. The device of claim 5, wherein each seed lens and color micro lens is composed of a material having a refractive index in a range between approximately 1.5 to 1.7.

11. The device of claim 5, wherein each color micro lens is composed of a dyed photoresist.

12. The device of claim 5, wherein each color micro lens has a thickness in a range between approximately 5000 to 8000 Å.

13. The device of claim 5, wherein the protective layer is composed of a transparent material.

14. The device of claim 5, wherein the protective layer is composed of a material having a refractive index of zero.

15. The device of claim 5, wherein the protective layer is composed of a thermosetting resin.

16. A method comprising:
providing a semiconductor substrate having a plurality of unit pixels formed therein;
forming a dielectric film over the semiconductor substrate; and then
forming a seed lens array including a plurality of seed lenses formed spaced apart by a gap of a predetermined width over the dielectric film; and then
forming a color micro lens array over the seed lens array, the color micro lens array including a color micro lens formed over and contacting a respective one of the seed lenses, wherein each color micro lens has a thickness that is one-half the predetermined width.

17. The method of claim 15, further comprising, after forming the color micro lens array, forming a protective layer over and contacting the color micro lens array, wherein the protective layer is composed of a transparent material having a reactive index of zero.

18. The method of claim 16, wherein the predetermined width is in a range between approximately 1.0 to 1.5 μm and each color micro lens has a thickness in a range between approximately 5000 to 8000 Å.

19. The method of claim 16, wherein the seed lens array and the color micro lens array are composed of materials having a refractive index in a range between approximately 1.5 to 1.7.

20. The device of claim 5, wherein each color micro lens is composed of a dyed photoresist.
